(19) United States
(12) Patent Application Publication
(10) Pub. No.: US 2011/0021132 A1
(43) Pub. Date: Jan. 27, 2011

(54) COMPUTER ENCLOSURE AND FAN BRACKET THEREOF

(75) Inventors: CHIA-SHIN CHOU, Tu-Cheng (TW); ZHEN-XING YE, Shenzhen City (CN); XIAN-XIU TANG, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (TW); HON HAI PRECISION INDUSTRY CO. LTD., Tu-Cheng (TW)

(21) Appl. No.: 12/542,709

(22) Filed: Aug. 18, 2009

(30) Foreign Application Priority Data
Jul. 24, 2009 (CN) 200910304777.6

(51) Int. Cl. H05K 5/00

(52) U.S. Cl. 454/184

(57) ABSTRACT

A computer enclosure includes a front panel. A fan bracket is provided for mounting a fan on the front panel. The fan bracket includes two parallel supporting beams installed on the front panel and two parallel mounting beams slidably fixed between the two supporting beams. The fan is adjustably mounted on the two mounting beams.

### BACKGROUND

1. Technical Field

The present disclosure relates to computer enclosures and, particularly, to a computer enclosure and a fan bracket mounted in the computer enclosure for mounting a fan.

2. Description of Related Art

A computer enclosure may include a system fan to dissipate heat. However, the system fan is usually fixedly attached to the computer enclosure, and is in the way when some electronic elements in the computer enclosure need to be changed.

### BRIEF DESCRIPTION OF THE DRAWINGS

FIG. 1 is a partially exploded, isometric view of an exemplary embodiment of a computer enclosure including a fan bracket.

FIG. 2 is an enlarged view of the circled portion II of the computer enclosure of FIG. 1.

FIG. 3 is an enlarged view of the circled portion III of the computer enclosure of FIG. 1.

FIG. 4 is an assembled view of the fan bracket of FIG. 1.

FIG. 5 is an assembled view of the computer enclosure of FIG. 1.

FIG. 6 is an enlarged view of the circled portion IV of the computer enclosure of FIG. 5.

### DETAILED DESCRIPTION

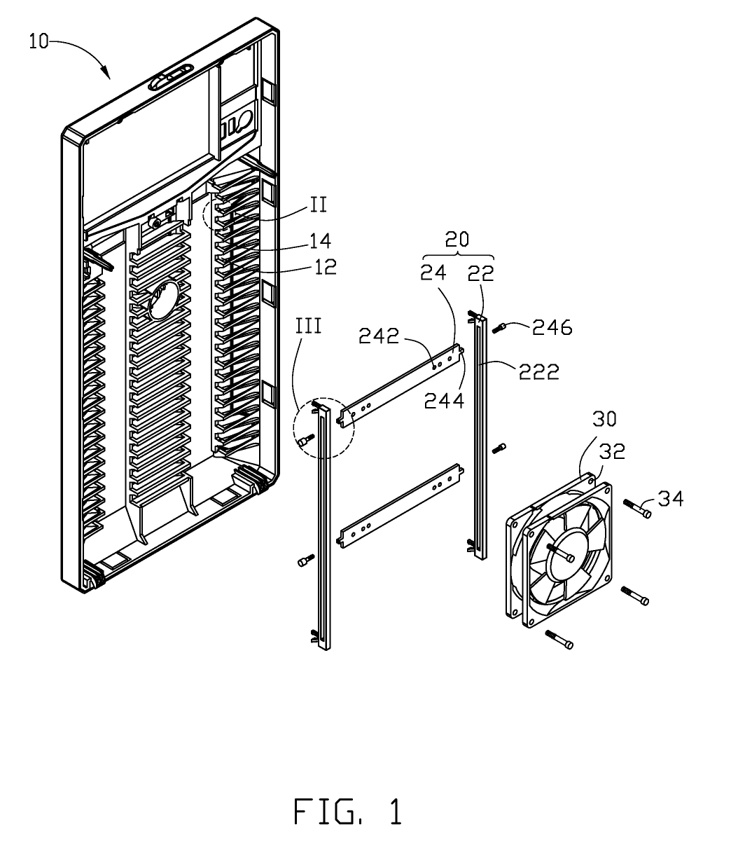

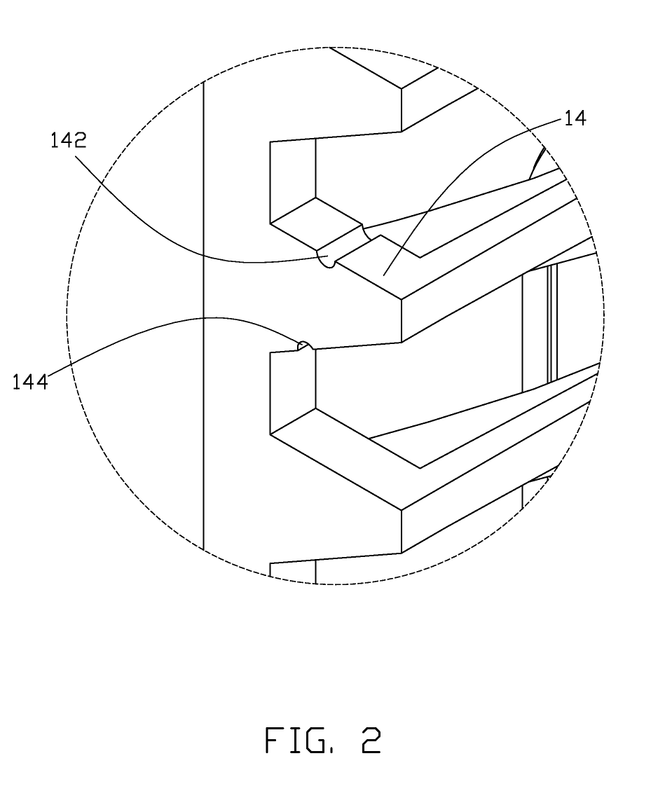

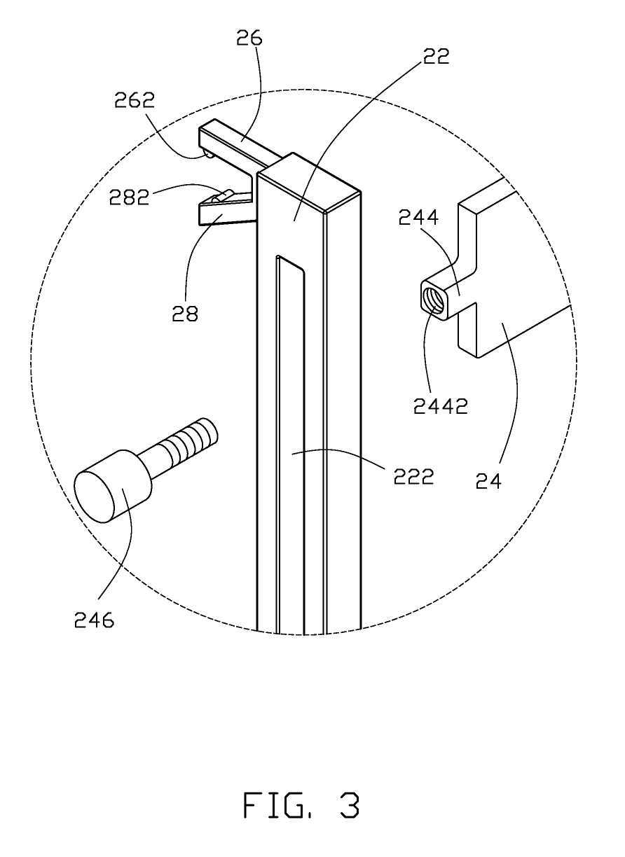

Referring to FIGS. 1 to 3, an exemplary embodiment of a computer enclosure includes a front panel 10, a fan bracket 20, and a fan 30.

The front panel 10 includes two mounting parts protruding from two sides of an inner wall of the front panel 10. Each of the two mounting parts defines a plurality of parallel openings 12 therebetween. An approximately trapezoidal-shaped tab 14 extend from between each two adjacent openings 12. There are four tabs 14 located at two ends of the two mounting parts of the front panel 10, and each define a first notch 142 on a top side thereof and a second notch 144 on a bottom side thereof.

The fan bracket 20 includes two supporting beams 22 each with a rectangular section, and two mounting beams 24 slidably fixed between the two supporting beams 24.

Each of the supporting beams 22 defines a sliding slot 222 thereof. Two projecting portions 26 and 28 extend from two opposite ends of each of the supporting beams 22, corresponding to the four tabs 14 located at four corners of the front panel 10. A first knob 262 and a second knob 282 extend from two opposite sides of the projecting portions 26 and 28, and face each other, corresponding to the first and second notches 142 and 144. In other embodiments, the first and second knobs 262 and 282, and the first and second notches 142 and 144 may be other latching configurations.

A plurality of mounting holes 242 are defined in each of the supporting beams 24 to mount the fan 30. Two protrusions 244 respectively extend from two opposite ends of each of the supporting beams 24. A screw hole 2442 is defined in each of the protrusions 244.

The fan 30 includes four pairs of mounting holes 32 defined in four corners thereof.

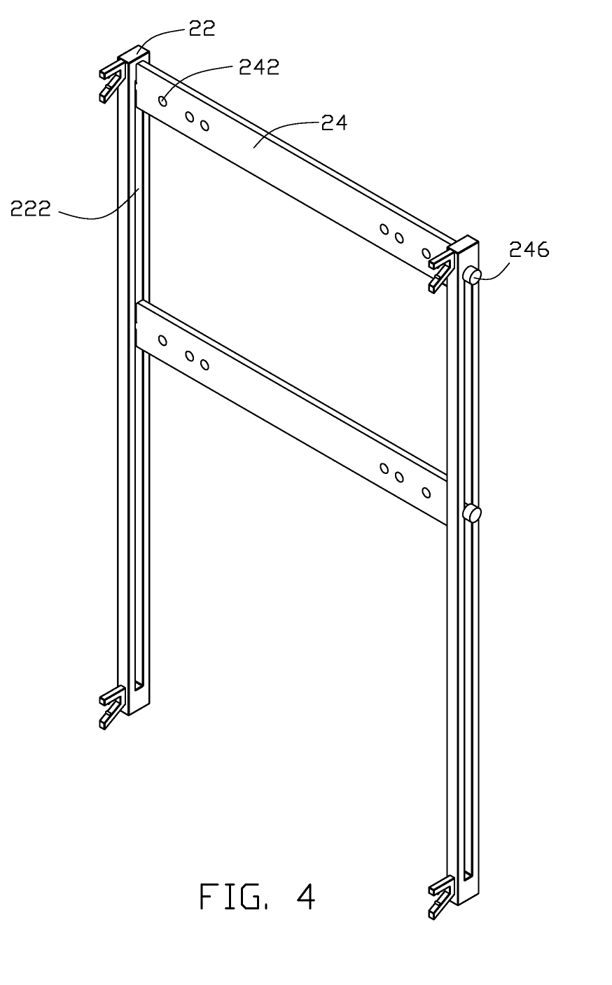

Referring to FIG. 4, in assembly of the fan bracket 20, the protrusions 244 of the supporting beams 24 are inserted into the sliding slots 222 of the supporting beams 22. According to the size of the fan 30, four screws 246 extend into the sliding slots 222 to threadedly engage in the four screw holes 2442 of the protrusions 244 of the supporting beams 24, thereby the supporting beams 24 are positioned on the supporting beams 22. A distance between the supporting beams 24 can be adjusted by slidably positioning the supporting beams 22 in the sliding slots 222.

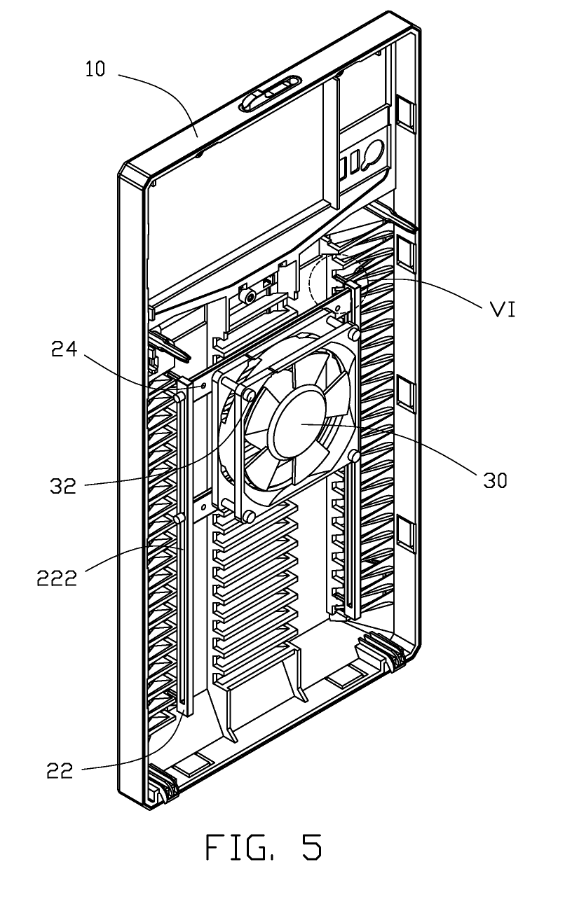

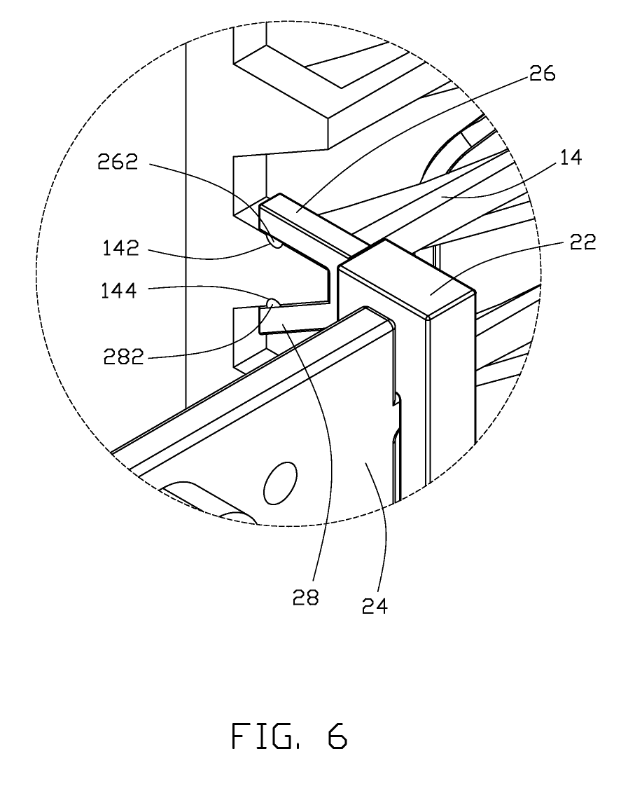

Referring to FIGS. 5 and 6, in assembly of the front panel 10, the fan bracket 20, and the fan 30; the first projecting portions 26 and the second projecting portions 28 are inserted into the openings 12 beside the tabs 14 and the first knobs 262 and the second knobs 282 of the supporting beams 22 are correspondingly latched in the first notches 142 and the second notches 144 of the four tabs 14, therefore the fan bracket 20 is positioned on the front panel 10. Four screws 34 are inserted into the mounting holes 32 and then screwed into four corresponding mounting holes 242 of the supporting beams 24. Therefore, the fan 30 is positioned on the front panel 10 via the fan bracket 20.

The supporting beams 24 can be adjustably positioned on the supporting beams 22 via the sliding slots 222, the fan 30 with different sizes can be attached to the fan bracket 20, which can effectively dissipate heat.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A computer enclosure, comprising:
a front panel;
a fan bracket comprising:
two parallel supporting beams attached to the front panel along a first direction; and
two parallel mounting beams slidably attached to the two supporting beams along a second direction perpendicular to the first direction, wherein a plurality of mounting holes are defined in each of the supporting beams; and
a fan attached to the mounting beams by fasteners engaging in the corresponding mounting holes.

2. The computer enclosure of claim 1, wherein the front panel includes four tabs located at four corners of the front panel, each of the tabs define a first latching element thereon, two projecting portions extend from two ends of each of the supporting beams corresponding to the four tabs, each of the two projecting portions define a second latching element operable to engage with the first latching element of the tabs.

3. The computer enclosure of claim 2, wherein the first latching element of each of the tabs includes a first notch and a second notch defined on a top side and a bottom side of the corresponding tab, the second latching element of each of the two projecting portions includes a first knob and a second knob extend from two opposite sides of the two projecting portions and face each other, corresponding to the first notch and the second notch.

4. The computer enclosure of claim 1, wherein each of the supporting beams defines a sliding slot therein, two protrusions extend from two ends of each of the supporting beams, a screw hole is defined in each of the protrusions, the protrusions of the supporting beams are inserted into the sliding slots of the supporting beams, four screws extend through the sliding slot to threadedly engage in the four screw hole of the protrusions of the supporting beams.

5. The computer enclosure of claim 1, wherein the fan includes four pairs of mounting holes defined in four corner of fan, the fan is mounted on the supporting beams via four screws inserted into the mounting holes and then screwed into four corresponding mounting holes of the two mounting beams.

6. The computer enclosure of claim 1, wherein the front panel defines a plurality of parallel openings therein, and each tab is formed between two adjacent openings.

7. A fan bracket, comprising:
two parallel supporting beams operable to be installed in a computer enclosure along a first direction; and
two parallel mounting beams slidably fixed between the two supporting beams along a second direction perpendicular to the first direction, wherein a plurality of mounting holes are defined in each of the supporting beams to mount a fan.

8. The fan bracket of claim 7, wherein two projecting portions extend from two ends of each of the supporting beams, each of the two projecting portions define a latching element operable to mount on the computer enclosure.

9. The fan bracket of claim 8, wherein the latching element of each of the two projecting portions includes a first knob and a second knob extend from two opposite sides of the two projecting portions.

10. The fan bracket of claim 7, wherein each of the supporting beams lengthways defines a sliding slot therein, two protrusions extend from two end of each of the supporting beams, a screw hole is defined in each of the protrusions, the protrusions of the supporting beams are inserted into the sliding slots of the supporting beams, four screws extend through the sliding slots and are screwed into the four screw hole of the protrusions of the supporting beams.
